(19) United States
(12) Patent Application Publication
(10) Pub. No.: US 2009/0239368 A1
(43) Pub. Date: Sep. 24, 2009

(54) Methods of Forming an Oxide Layer and Methods of Forming a Gate Using the Same

(75) Inventors: Jae Hwa Park, Gyeonggi-do (KR); Gil-Heyun Choi, Seoul (KR); Hee-Sook Park, Seoul (KR); Jong-Min Baek, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/408,994

(22) Filed: Mar. 23, 2009

(30) Foreign Application Priority Data
Mar. 24, 2008 (KR) 2008-26819

(51) Int. Cl. H01L 21/336; H01L 21/469; H01L 21/314

(52) U.S. Cl. 438/592; 438/768; 438/788; 438/594; 438/595; 257/E21.409; 257/E21.487; 257/E21.266

(57) ABSTRACT

An oxide layer is selectively formed on a layer including silicon by a plasma process using hydrogen gas and a gas including oxygen. The hydrogen gas is controlled to have a flow rate less than about 50 percent of an overall flow rate by adding helium gas to the plasma process.

### FIELD OF THE INVENTION

Example embodiments relate to methods of forming an oxide layer and methods of forming a gate using the methods. More particularly, example embodiments relate to methods of forming an oxide layer having high reliability by selectively oxidizing only silicon, and methods of forming a gate using the methods.

### BACKGROUND OF THE INVENTION

A process of forming a thin film, such as a polysilicon layer, an oxide layer, etc., and a process of patterning the thin film may be performed to form a semiconductor device. For example, a dry etching process, such as a plasma etching or a reactive ion etching (RIE) process, may be performed after forming a gate electrode layer on a gate oxide layer in a process of forming a gate of a transistor. However, when the gate electrode layer is etched by the dry etching process, an edge portion of the gate oxide layer may be damaged by the dry etching process. The damage to the edge portion of the gate oxide layer may have effects on a breakdown voltage of the gate oxide layer, so that a semiconductor device may have poor reliability. Thus, an additional oxidation process called a reoxidation process may be performed to cure the damage to the edge portion of the gate oxide layer after etching the gate electrode layer.

As the design rule of semiconductor devices decreases, the resistance of wires needs to be reduced. Particularly, a metal gate electrode, in which a metal having a low specific resistance or a metal silicide layer is deposited on a polysilicon layer, is used as a gate electrode to reduce the height, the line width and the resistance of the gate electrode.

One problem of forming the metal gate electrode is that a surface of the metal gate electrode is oxidized when a reoxidation process for curing a gate oxide layer is performed. When the metal gate electrode includes a material having low oxidation resistance, a surface of the metal gate electrode may be oxidized during the reoxidation process. As a result, the metal gate electrode may have a deformed shape and high resistance, and adjacent metal gate electrodes may be electrically connected with each other. A selective reoxidation process controlling the oxidation of a metal material during the reoxidation process of the metal gate electrode and selectively oxidizing a polysilicon layer or a silicon substrate is applied to prevent the above problems. For example, the oxidation of the metal gate electrode may be controlled, and the polysilicon layer and the substrate may be selectively oxidized by injecting hydrogen gas as well as oxygen gas to the reoxidation process. However, when at least one of an electrode, a barrier layer, an ohmic layer includes a material having low oxidation resistance such as titanium, a selective oxidation process in a radical oxidation process using a conventional furnace may be impossible at a high temperature. Although an oxidation blocking layer is formed on a sidewall of the metal to overcome the above problems, forming the oxidation blocking layer may not enhance the degree of integration of a semiconductor device. A selective oxidation process using a plasma is performed.

Even when the plasma oxidation process is performed, the metal gate electrode may be oxidized as a process temperature is increased. Thus, increasing an oxidation temperature to greater than about 500° C. may be difficult in the selective oxidation process. When the oxidation temperature is low, obtaining a gate oxide layer pattern of good quality may be difficult because curing characteristics of the gate oxide layer pattern by the oxidation process at a low temperature may not be good. Particularly, a breakdown voltage may be lowered when the gate oxide layer is reoxidized at a low temperature.

A flow rate of hydrogen gas is largely increased to control the oxidation of the metal gate electrode. Particularly, the flow rate of hydrogen gas is largely increased for performing the oxidation process at a high temperature. However, when the flow rate of hydrogen gas is largely increased, trap sites due to the hydrogen gas may be generated at an interface between a silicon substrate and the gate oxide layer. When the flow rate of hydrogen gas is largely increased, a transistor may have poor reliability due to the trap sites in the gate oxide layer.

Improving curing characteristics of the gate oxide layer while controlling the oxidation of the metal gate electrode in the oxidation process may be difficult. Thus, manufacturing a transistor including a metal gate electrode having high reliability and enhanced breakdown voltage may be difficult.

### SUMMARY

Example embodiments provide methods of forming an oxide layer controlling an oxidation to a metal, reducing trap sites and having high reliability.

Example embodiments provide methods of forming a gate including the oxide layer.

According to some example embodiments, there is provided methods of forming an oxide layer. An oxide layer is selectively formed on a layer including silicon by a plasma process using hydrogen gas and a gas including oxygen. The hydrogen gas is controlled to have a flow rate less than about 50 percent of an overall flow rate by adding helium gas to the plasma process.

In an example embodiment, a percentage of a flow rate of the hydrogen with respect to a combination of the gas including oxygen and the hydrogen may be in a range of about 15% to about 97%.

In an example embodiment, the gas including oxygen may include oxygen (O₂), ozone (O₃), nitric oxide (NO) and nitrous oxide (N₂O), etc.

In an example embodiment, the plasma process may be performed at a temperature of about 200° C. to about 1,000° C.

In an example embodiment, the layer including silicon may include a single-crystalline silicon substrate or a polysilicon layer.

In an example embodiment, a metal material may further be formed on a portion of the layer including silicon prior to forming the oxide layer.

According to some example embodiments, there is provided a method of forming a gate. A conductive layer including metal, a gate oxide layer and a polysilicon layer is deposited on a substrate. The conductive layer including metal, the gate oxide layer and the polysilicon layer are subsequently patterned to form a conductive layer pattern, a gate oxide layer pattern and a polysilicon layer pattern. An oxide layer is selectively formed on a sidewall of the polysilicon layer pattern by a plasma process using hydrogen gas and a gas including oxygen. The hydrogen gas is controlled to have a flow rate less than about 50 percent of an overall flow rate by adding helium gas to the plasma process.

In an example embodiment, a percentage of a flow rate of the hydrogen with respect to a combination of the gas including oxygen and the hydrogen may be in a range of about 15% to about 97%.

In an example embodiment, the plasma process may be performed at a temperature of about 200° C. to about 1,000° C.

In an example embodiment, the conductive layer may include tungsten.

In an example embodiment, a barrier metal layer pattern may be formed between the polysilicon layer and the conductive layer.

In an example embodiment, the barrier metal layer may include tungsten nitride, titanium nitride and tantalum nitride, etc.

In an example embodiment, a hard mask pattern may be further formed on the conductive layer.

According to some example embodiments, there is provided a method of forming a gate. A tunnel oxide layer, a polysilicon layer, a dielectric layer and a conductive layer including metal are formed on a substrate. The conductive layer, the dielectric layer, the polysilicon layer and the tunnel oxide layer are patterned to form a tunnel oxide layer pattern, a floating gate pattern, a dielectric layer pattern and a control gate pattern. An oxide layer on a sidewall of the floating gate pattern is selectively formed by a plasma process using hydrogen gas and a gas including oxygen. The hydrogen gas is controlled to have a flow rate less than about 50 percent of an overall flow rate by adding helium gas to the plasma process.

In an example embodiment, a percentage of a flow rate of the hydrogen with respect to a combination of the gas including oxygen and the hydrogen may be in a range of about 15% to about 97%.

In an example embodiment, the plasma process may be performed at a temperature of about 200° C. to about 1,000° C.

In an example embodiment, the conductive layer may be formed by depositing tungsten.

In an example embodiment, the conductive layer may be formed by depositing a polysilicon layer and a metal layer including tungsten.

In an example embodiment, the oxide layer formed by the plasma process may also be formed on a polysilicon surface of the control gate pattern.

According to some example embodiments, an oxide layer may be formed by a plasma reoxidation process under a low hydrogen partial pressure and at a high temperature. Even when the hydrogen partial pressure is under about 0.5, only silicon is oxidized to form a silicon oxide layer without oxidizing a metal material. Trap sites in an interface between a silicon layer and a silicon oxide layer formed by oxidizing the silicon layer may be reduced because the hydrogen partial pressure is low. Thus, the silicon oxide layer may be of good quality. Also, even when a transistor having a metal material and a silicon layer is reoxidized at a high temperature, the metal material may not be oxidized and the silicon layer may be reoxidized to form a silicon oxide layer, so that etching damage may be prevented in the reoxidation process. Particularly, an oxidation rate of a silicon layer may be hardly reduced when compared to a plasma reoxidation process in which helium gas is not added with a plasma reoxidation process in which helium gas is added to lower a hydrogen partial pressure. Thus, even when helium gas is added in a plasma reoxidation process, the process time of forming a silicon oxide layer may not be increased.

### BRIEF DESCRIPTION OF THE DRAWINGS

Example embodiments will be more clearly understood from the following detailed description taken in conjunction with the accompanying drawings. FIGS. 1 to 12 represent non-limiting, example embodiments as described herein.

FIG. 1 is a cross-sectional view illustrating a method of forming a silicon oxide layer in accordance with some example embodiments;

FIGS. 2 to 4 are cross-sectional views illustrating a method of forming a gate in accordance with other example embodiments;

FIG. 5 is a cross-sectional view illustrating a method of forming a transistor in accordance with some example embodiments;

FIGS. 6 to 8 are cross-sectional views illustrating a method of forming a gate of a non-volatile memory device in accordance with some example embodiments;

FIG. 9 is a cross-sectional view illustrating a method of forming a non-volatile memory cell in accordance with some example embodiments;

FIG. 10 is a graph illustrating breakdown voltages of a transistor according to temperatures of a plasma oxidation process in accordance with Comparative Examples;

FIG. 11 is a graph illustrating each of oxidation rates of transistors in accordance with Examples 1 to 2, and Comparative Examples 4 to 6 according to oxidation conditions; and

FIG. 12 is a graph illustrating the reliability of each of transistors in accordance with Comparative Examples 7 to 10.

### DETAILED DESCRIPTION OF THE EMBODIMENTS

This application claims priority under 35 U.S.C. § 119 to Korean Patent Application No. 2008-26819, filed on Mar. 24, 2008 in the Korean Intellectual Property Office (KIPO), the contents of which are herein incorporated by reference in their entirety.

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

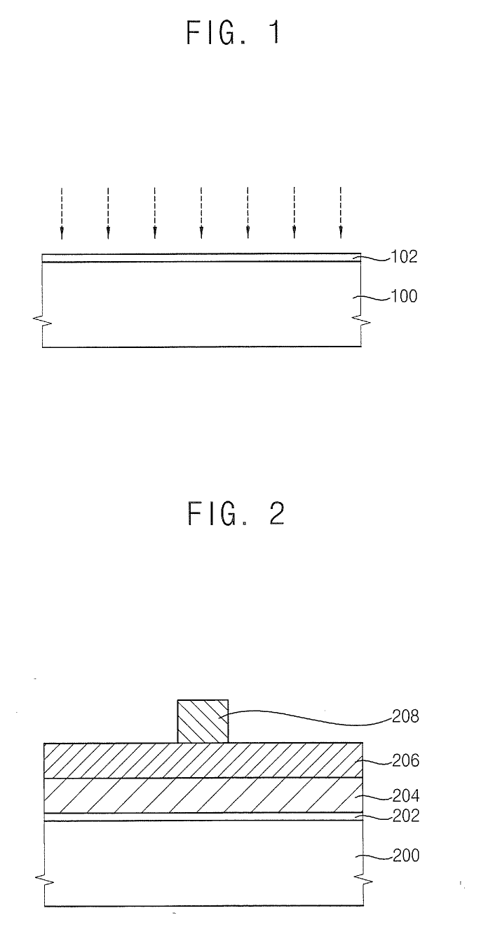

FIG. 1 is a cross-sectional view illustrating a method of forming a silicon oxide layer in accordance with some example embodiments.

Referring to FIG. 1, a single-crystalline silicon substrate 100 is provided. Although not shown in FIG. 1, at least one pattern of a silicon pattern and a metal pattern may be formed on the single-crystalline silicon substrate 100. Alternatively, as shown in FIG. 1, a pattern may not be formed on the single-crystalline silicon substrate 100.

After the single-crystalline silicon substrate 100 is provided into a chamber, hydrogen gas, helium gas and a gas including oxygen are injected into the chamber and a plasma oxidation process is performed. A surface of the single-crystalline silicon substrate 100 is oxidized by the plasma oxidation process to form a silicon oxide layer 102.

The gas including oxygen is provided as an oxidizing agent for oxidizing the single-crystalline silicon substrate 100. Examples of the gas including oxygen may include oxygen (O₂), ozone (O₃), nitric oxide (NO), nitrous oxide (N₂O), etc. These may be used alone or in a combination thereof.

The hydrogen gas is provided to control the oxidation of a metal material and only oxidize the single-crystalline silicon substrate 100 or a surface of a silicon material. A percentage of a flow rate of the hydrogen gas with respect to a combination of the gas including oxygen and the hydrogen gas may be in a range of about 15% to about 97%. That is, a ratio of the hydrogen gas and a combination of the gas including oxygen and the hydrogen gas may be about 1:0.15 to about 1:0.97.

Generally, a percentage of a flow rate of the hydrogen gas with respect to a combination of the gas including oxygen and the hydrogen gas is greater than about 90% in order not to oxidize a metal material in a plasma oxidation process in which helium gas is not added. However, when a selective plasma oxidation process in which helium gas has been added in accordance with an embodiment is performed, a percentage of a flow rate of the hydrogen gas with respect to a combination of the gas including oxygen and the hydrogen gas may be in a range of about 15% to about 97%, which is wider compared to the general plasma oxidation process in which helium gas is not added. Even when the flow rate of the hydrogen gas with respect to a combination of the gas including oxygen and the hydrogen gas is decreased to about 15%, silicon may be oxidized without oxidizing a metal material.

The helium gas is provided to lower a ratio of the partial pressure of the hydrogen gas. The ratio of the partial pressure of the hydrogen may be lowered by increasing a flow rate of the helium gas. The ratio of the partial pressure represents a ratio of a specific gas with respect to an overall gas provided into the chamber.

Forming a silicon oxide layer of good quality may be difficult by providing the hydrogen gas having a flow rate substantially larger than that of about 50% of the overall gas because when the hydrogen gas has a flow rate substantially larger than that of about 50% of the overall gas, trap sites are increased in a silicon oxide layer. Accordingly, the helium gas is added to a reaction gas so that the hydrogen gas has a flow rate substantially smaller than that of about 50% of the overall gas. That is, the hydrogen gas has a ratio of a partial pressure substantially smaller than about 0.5 in the plasma oxidation process. More preferably, the helium gas is added, so that the hydrogen gas has a ratio of a partial pressure substantially smaller than about 0.2.

When the partial pressure of the hydrogen gas is reduced by adding the helium gas, a metal may be hardly oxidized and only silicon may be oxidized. An oxidation rate may not be lowered by adding the helium gas compared to when helium gas is not added. Thus, a time for forming a silicon oxide layer may not be increased by adding the helium gas.

The plasma oxidation process may be performed at a temperature of about 200° C. to about 1,000° C. A metal oxidation may be controlled by adding the helium gas even when the oxidation process is performed at a temperature over about 500° C. Accordingly, a silicon oxide layer of good quality may be formed by performing the oxidation process at a high temperature and in which helium gas is not added.

FIGS. 2 to 4 are cross-sectional views illustrating a method of forming a gate in FIG. 1.

Referring to FIG. 2, a gate oxide layer 202, a polysilicon layer 204 and a conductive layer 260 including metal is deposited on a single-crystalline silicon substrate 200.

The gate oxide layer 202 may be formed using silicon oxide formed through a thermal oxidation process. The polysilicon layer 204 may be formed by a chemical vapor deposition (CVD) process. The conductive layer 206 may be formed using a material such as tungsten, tungsten silicide, titanium, titanium silicide, etc. These may be used alone or in a combination thereof. In an example embodiment, the conductive layer 206 is formed using tungsten.

A hard mask pattern 208 is formed on the conductive layer 206. The hard mask pattern 208 may be formed by depositing a silicon nitride layer on the conductive layer 206 and patterning the silicon nitride layer.

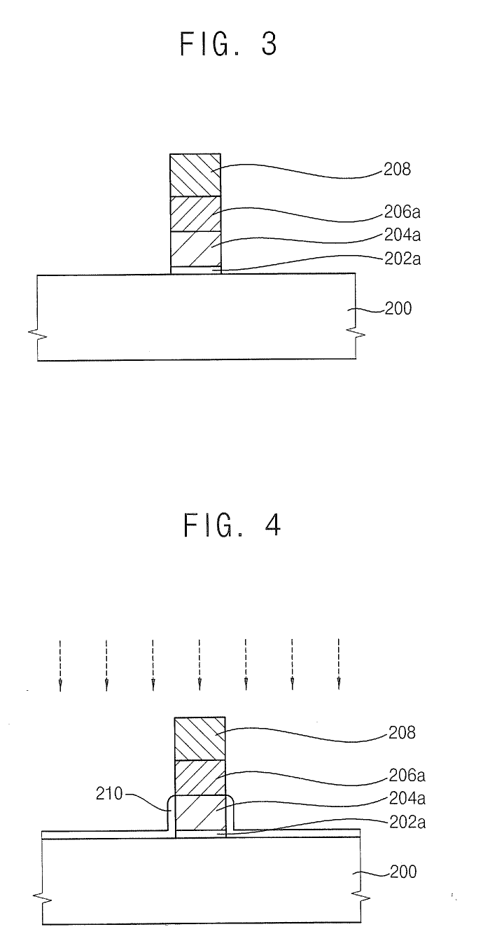

Referring to FIG. 3, the conductive layer, the polysilicon layer 204 and the gate oxide layer 202 are anisotropically etched using the hard mask pattern 208 as an etch mask. A gate structure in which a gate oxide layer pattern 202a, a polysilicon pattern 204a and a conductive layer pattern 206a are deposited is formed. The anisotropic etch process may include a dry etching process such as a plasma etching process, a reactive ion etching (RIE) process, etc.

When an anisotropic etching process is performed, an edge portion of the gate oxide layer pattern 202a may be damaged. Thus, a reoxidation process for curing the etching damage is required.

Referring to FIG. 4, the single-crystalline silicon substrate 200 including the gate structure is reoxidized to form a silicon oxide layer 210 on the single-crystalline silicon substrate 200 and the polysilicon pattern 204a. When the reoxidation process is performed, the silicon oxide layer 210 may not be formed on a sidewall of the conductive layer pattern 206a including a metal.

The single-crystalline silicon substrate 200 including the gate structure is provided into a chamber, and then a plasma reoxidation process is performed by injecting hydrogen gas, helium gas and a gas including oxygen into the single-crystalline silicon substrate 200 in the chamber.

The helium gas is provided to reduce the partial pressure of the hydrogen gas. The helium gas is provided to maintain a ratio of the partial pressure of the hydrogen gas less than about 0.5. Trap sites at an interface between the silicon oxide layer 210 and the single-crystalline silicon substrate 200 may be reduced by decreasing the ratio of the partial pressure of the hydrogen gas.

A percentage of a flow rate of the hydrogen gas with respect to a combination of the gas including oxygen and the hydrogen gas may be in a range of about 15% to about 97%.

The plasma reoxidation process may be performed at a temperature of about 200° C. to about 1,000° C. The plasma reoxidation process may be performed at a temperature of about 500° C. to about 800° C. When the plasma reoxidation process is performed at a temperature greater than about 500° C., the silicon oxide layer may be of good quality and a transistor having the silicon oxide layer may have improved breakdown voltage characteristics.

The plasma reoxidation process may be performed using a method substantially the same as that of forming an oxide layer described with reference to FIG. 1.

When the plasma reoxidation process is performed, the silicon oxide layer 210 may be selectively formed on the single-crystalline silicon substrate 200 and the polysilicon pattern 204a to cure the gate oxide layer pattern 202a. Also, the hydrogen gas has a low partial pressure when the plasma reoxidation process is performed. Accordingly, trap sites at an interface between the gate oxide layer pattern 202a and the single-crystalline silicon substrate 200 may be reduced. As a result, the gate oxide layer pattern 202a may be of good quality. A transistor including the gate structure may have a high breakdown voltage.

The conductive layer pattern 206a including metal may be hardly oxidized by the plasma reoxidation process. When the conductive layer pattern 206a including metal is oxidized, a metal oxide grows laterally so that adjacent conductive layer patterns (not illustrated) may be electrically connected to each other by the metal oxide growth. However, because the conductive layer pattern 206a may be hardly oxidized in spite of the low partial pressure of the hydrogen gas, defects due to the oxidation of the conductive layer pattern 206a may be prevented.

A gate structure of which damage is cured is formed by the plasma reoxidation process.

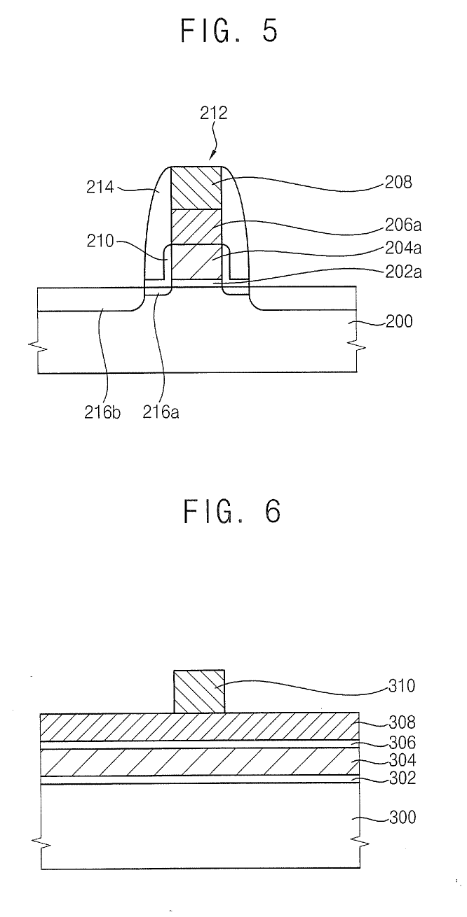

FIG. 5 is a cross-sectional view illustrating a method of forming a transistor in accordance with some example embodiments;

A transistor illustrated in FIG. 5 may include the gate structure described with reference to FIGS. 2 to 4.

Referring to FIG. 5, impurities are implanted onto the silicon substrate 200 adjacent to a gate structure 212 to form a lightly doped source/drain region 216a. A spacer 214 is formed on a sidewall of the gate 212. Impurities are implanted onto the substrate adjacent to the spacer 214 to form a highly doped source/drain region 216b.

A process of forming the lightly doped source/drain region 216a may be omitted. That is, the highly doped source/drain region 216b is formed without forming the highly doped source/drain region 216a after forming the spacer 214.

The transistor in accordance with an example embodiment may have a high breakdown voltage and good reliability.

The transistor may be used as a switching device of a semiconductor device. For example, the transistor may be used as a cell transistor of a dynamic random access memory (DRAM) device or a static random access memory (SRAM) device. After forming the transistor, a DRAM device or an SRAM device may be manufactured by performing a general process of manufacturing a DRAM device or an SRAM device. The transistor may be used as a switching device of a peripheral circuit of a memory device.

FIGS. 6 to 8 are cross-sectional views illustrating a method of forming a gate of a non-volatile memory device in accordance with some example embodiments.

Referring to FIG. 6, a shallow trench isolation process is performed on a single-crystalline silicon substrate 300 to form an isolation layer pattern (not illustrated).

A tunnel oxide layer 302 is formed on a single-crystalline silicon substrate 300 on which the isolation layer pattern is formed. The tunnel oxide layer 302 may include silicon oxide formed by a thermal oxidation process. A polysilicon layer for a floating gate (not illustrated) is formed on the tunnel oxide layer 302. A preliminary floating gate pattern 304 having a line shape extending in a direction substantially the same as that of the isolation layer pattern is formed by patterning the polysilicon layer.

A dielectric layer 306 is formed on the preliminary floating gate pattern 304. The dielectric layer 306 may have a structure in which silicon oxide, silicon nitride and silicon oxide are sequentially stacked. The dielectric layer 306 may be formed by depositing a metal oxide having a dielectric constant greater than that of silicon nitride. The metal oxide may include zirconium oxide (ZrOₓ), aluminum oxide (AlOₓ), hafnium oxide (HfOₓ), tantalum oxide (TaOₓ), lanthanum oxide (LaO), hafnium silicon oxide (HfSiO), hafnium aluminum oxide (HfAlO), titanium oxide (TiO), lanthanum aluminum oxide (LaAlOₓ), barium zirconium oxide (BaZrOₓ), strontium zirconium oxide (SrZrOₓ), etc. These may be used alone or in a combination thereof.

A conductive layer 308 including metal is formed on the dielectric layer 306. Examples of the metal may include tungsten, tungsten silicide, cobalt silicide, nickel suicide, titanium silicide, etc. These are may be used in alone or a combination thereof. A metal nitride layer (not illustrated) is formed between the conductive layer 308 and the dielectric layer 306 to improve adhesive characteristics therebetween. The metal nitride layer may include a tungsten nitride layer, a titanium nitride layer, a tantalum nitride layer, etc. These are may be used alone or in a combination thereof.

A hard mask pattern 310 is formed on the conductive layer 308. The hard mask pattern 310 may be formed by depositing a silicon nitride layer and patterning the silicon nitride layer.

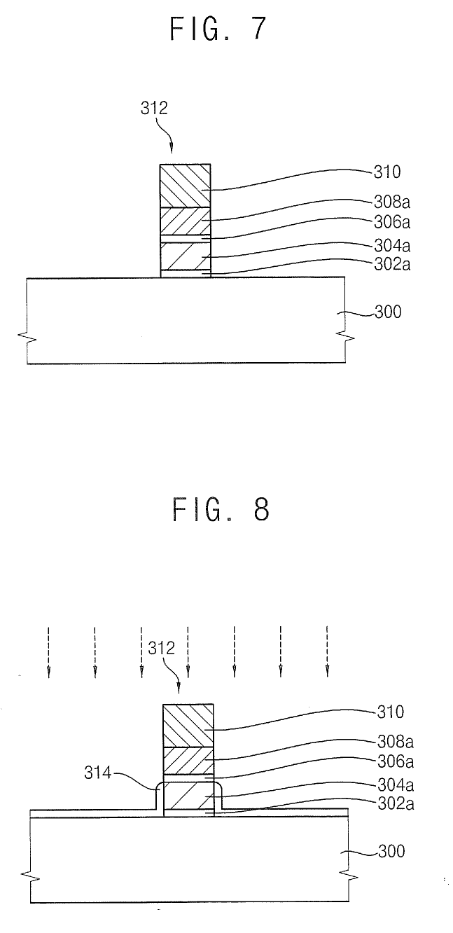

Referring to FIG. 7, the conductive layer 308, the dielectric layer 306, the preliminary floating gate pattern 304 and the tunnel oxide layer 302 are etched using the hard mask pattern 310 as an etching mask. A gate structure 312 including a tunnel oxide layer pattern 302a, a floating gate pattern 304a, a dielectric layer pattern 306a and a control gate pattern 308a is formed on the single-crystalline silicon substrate 300 by the etching process.

Referring to FIG. 8, a silicon oxide layer 314 is formed on the single-crystalline silicon substrate 300 and the floating gate pattern 304a by reoxidizing the gate structure 312. The silicon oxide layer may not be formed on a sidewall of the control gate pattern 308a including the metal by the reoxidation process.

The single-crystalline silicon substrate 300 on which the gate structure 312 is formed is provided into a chamber. A gas including oxygen and hydrogen gas are provided into the chamber. A plasma oxidation process is performed to control a ratio of the partial pressure of the hydrogen gas of less than about 0.5 by adding helium gas into the chamber. A percentage of a flow rate of the hydrogen gas with respect to a combination of the gas including oxygen and the hydrogen gas may be in a range of about 15% to about 97%. The plasma oxidation process is performed at a temperature of about 200° C. to about 1,000° C.

The plasma oxidation process is a method substantially the same as those described with reference to FIGS. 1 to 4.

The silicon oxide layer 314 is selectively formed on the single-crystalline silicon substrate 300 and the floating gate pattern 304a to cure the tunnel oxide layer pattern 302a by performing the plasma oxidation process. A gate structure of a non-volatile memory device is formed.

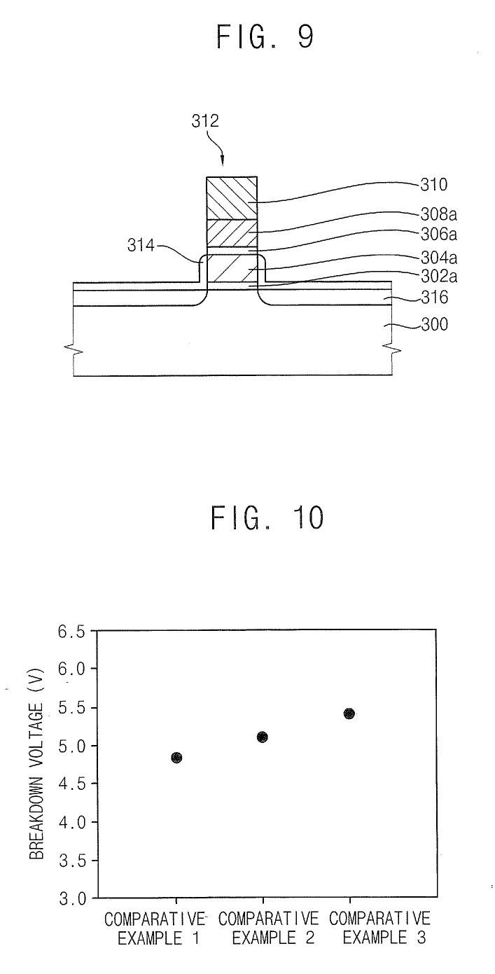

FIG. 9 is a cross-sectional view illustrating a method of forming a non-volatile memory cell in accordance with some example embodiments.

A non-volatile memory cell in FIG. 9 may be formed by performing the following process after forming a gate structure using a method described with reference to FIGS. 6 to 8.

Referring to FIG. 9, impurities are implanted into a surface of the substrate 300 adjacent the gate structure 312 formed by the method described with reference to FIGS. 6 to 8, so that a source/drain 316 is formed. Accordingly, a non-volatile memory device is formed.

The non-volatile memory device may be used as a cell of a NAND flash memory device. Alternatively, the non-volatile memory device may be used as a cell of a NOR flash memory device.

Hereinafter, characteristics of MOS transistors formed using various process conditions of a reoxidation process for reoxidizing a gate oxide layer of the MOS transistors are compared with each other.

FIG. 10 is a graph illustrating breakdown voltages of a transistor according to temperatures of a plasma oxidation process in accordance with Comparative Examples 1 to 3.

### Comparative Example 1

Gate structures were formed using a plasma reoxidation process using oxygen gas and hydrogen gas without adding helium gas. A gate was formed on a substrate and an impurity region is formed. A plasma reoxidation process using oxygen gas and hydrogen gas and in which helium gas is not added was performed to form a transistor at a temperature of about 450° C.

### Comparative Example 2

Gate structures were formed using a plasma reoxidation process using oxygen gas and hydrogen gas and in which helium gas is not added. A gate was formed on a substrate and an impurity region is formed. A plasma reoxidation process using oxygen gas and hydrogen gas and in which helium gas is not added was performed to form a transistor at a temperature of about 700° C.

### Comparative Example 3

Gate structures were formed using a plasma reoxidation process using oxygen gas and hydrogen gas and in which helium gas is not added. A gate was formed on a substrate and an impurity region is formed. A plasma reoxidation process using oxygen gas and hydrogen gas and in which helium gas is not added was performed to form a transistor at a temperature of about 800° C.

Breakdown voltages of transistors formed at temperatures of about 450° C., about 700° C. and about 800° C. are illustrated in FIG. 10, respectively.

As illustrated in FIG. 10, as a process temperature is increased, a breakdown voltage of a transistor is increased. Thus, as the temperature of the plasma reoxidation process is increased, the durability of a gate oxide layer may be increased.

Even when the plasma reoxidation process using helium gas in accordance with some example embodiments may be performed at a temperature of about 200° C. to 1,000° C., especially at a temperature greater than about 500° C., a metal oxidation may not occur. Accordingly, a transistor having a high breakdown voltage may be formed by increasing the temperature of the plasma reoxidation process.

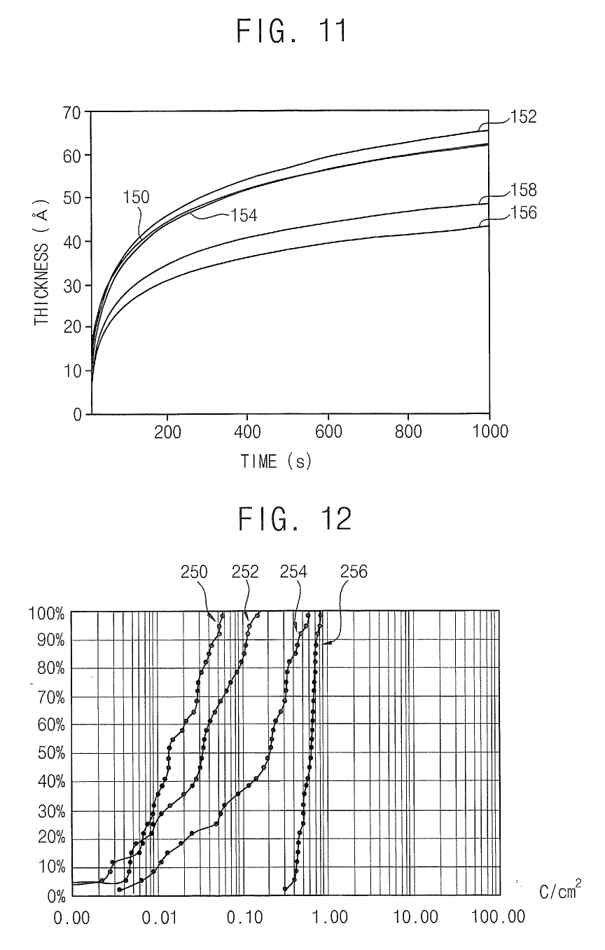

FIG. 11 is a graph illustrating each of oxidation rates of transistors in accordance with Examples 1 and 2, and Comparative Examples 4 to 6 according to oxidation conditions.

Plasma reoxidation processes having the following conditions were performed on transistors in accordance with Examples 1 and 2, and Comparative Examples 4 to 6, respectively.

TABLE 1

| | Oxygen Gas | Hydrogen Gas | Helium Gas | Argon Gas |
|---|---|---|---|---|
| | (sccm) | (sccm) | (sccm) | (sccm) |
| Example 1 | 20 | 380 | 800 | |
| Example 2 | 20 | 380 | 1,200 | |
| Comparative | 20 | 380 | | |
| Example 4 | | | | |
| Comparative | 20 | 380 | | 800 |
| Example 5 | | | | |
| Comparative | 20 | 380 | | 400 |
| Example 6 | | | | |

Referring to FIG. 11, reference numerals 150 and 152 represent oxidation rates of Examples 1 and 2, respectively, and reference numerals 154, 156 and 158 represent oxidation rates of Comparative Examples 4 to 6, respectively. When oxidation rates of Example 1 and 2, and Comparative Example 4 are compared to each other, the oxidation rates are substantially similar to each other. That is, even when helium gas is added to lower the partial pressure of hydrogen gas, the oxidation rate is not reduced.

Referring to FIG. 11, reference numerals 156 and 158 represent oxidation rates of Comparative Examples 5 and 6, respectively. According to Comparative Examples 5 and 6, argon gas as an inert gas was added in a plasma oxidation process using oxygen gas and hydrogen gas to lower the partial pressure of hydrogen gas. According to Comparative Example 4, a plasma oxidation process using only oxygen gas and hydrogen gas was performed. When Comparative Examples 5 and 6, and Comparative Example 4 are compared to each other, the oxidation rates of Comparative Examples 4 and 5 are lower than that of Comparative Example 4.

When the partial pressure of hydrogen gas is lowered using argon gas, not helium gas, the oxidation rate is reduced. Particularly, when a flow rate of the argon gas is increased, the oxidation rate is rapidly reduced. Thus, the flow rate of the argon gas is reduced to maintain the oxidation rate. Injecting sufficient argon gas to lower the partial pressure of hydrogen gas may be difficult.

According to Examples 1 and 2, and Comparative Examples 4 to 6, when a silicon oxide layer is formed, the partial pressure of hydrogen gas may be lowered and a high oxidation rate may be maintained by adding helium gas.

FIG. 12 is a graph illustrating the reliability of each of transistors in accordance with Comparative Examples 7 to 10.

Transistors in accordance with Comparative Examples 7 to 10 were formed by reoxidizing the transistors under percentages of hydrogen partial pressures of about 95%, 66%, 50% and 1%, respectively, after patterning each of gates of the transistors. Reference numerals 250, 252, 254 and 256 represent the reliability of Comparative Examples 7 to 10, respectively.

Referring to FIG. 12, when the partial pressure of the hydrogen is low, a gate oxide layer of a transistor has high reliability. Thus, a gate oxide layer having high reliability may be obtained because a plasma reoxidation process may be performed under a low hydrogen partial pressure by adding helium gas.

According to some example embodiments, a plasma reoxidation process in which helium gas has been added may be used for curing etching damage generated in a process forming a gate structure. However, the plasma reoxidation process in which helium gas has been added may be applied to various processes for forming an oxide layer. For example, the plasma reoxidation process may be used for forming a thin silicon oxide layer such as a gate oxide layer, a tunnel oxide layer, a blocking dielectric layer, etc. Additionally, the plasma reoxidation process may be used for forming an inner oxide layer for curing an inner surface of a trench in an isolation process.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of forming an oxide layer, comprising:
oxidizing an electrically conductive layer comprising silicon by exposing a surface of the electrically conductive layer in a processing apparatus to an oxidizing plasma containing hydrogen, helium and oxygen, said exposing comprising supplying the processing apparatus with a helium gas at a first flow rate, an oxygen-containing gas at a second flow rate and a hydrogen gas at a third flow rate less than about 50% of a sum of the first, second and third flow rates.

2. The method of claim 1, wherein the third flow rate is in a range from about 0.15 times to about 0.97 times of a sum of the second flow rate and a third flow rate.

3. The method of claim 1, wherein the oxygen-containing gas is selected from a group consisting of oxygen (O2), ozone (O3), nitric oxide (NO) and nitrous oxide (N2O).

4. The method of claim 1, wherein said oxidizing is performed at a temperature in a range from about 200° C. to about 1000° C.

5. The method of claim 1, wherein the electrically conductive layer is selected from a group consisting of single crystal silicon and polycrystalline silicon.

6. The method of claim 1, wherein said exposing comprises exposing the surface of the electrically conductive layer and a metal layer on the electrically conductive layer to the oxidizing plasma.

7. A method of forming an integrated circuit device, comprising:
forming a gate oxide layer, a polysilicon layer and a metal-containing layer in sequence on a substrate;
patterning the metal-containing layer, the polysilicon layer and the gate oxide layer to define a sidewall of the patterned gate oxide layer, the patterned polysilicon layer and the patterned metal-containing layer; and
exposing the sidewall in a processing apparatus to an oxidizing plasma containing hydrogen, helium and oxygen, said exposing comprising supplying the processing apparatus with a helium gas at a first flow rate, an oxygen-containing gas at a second flow rate and a hydrogen gas at a third flow rate less than about 50% of a sum of the first, second and third flow rates.

8. The method of claim 7, wherein the third flow rate is in a range from about 0.15 times to about 0.97 times of a sum of the second flow rate and the third flow rate.

9. The method of claim 7, wherein the oxygen-containing gas is selected from a group consisting of oxygen (O2), ozone (O3), nitric oxide (NO) and nitrous oxide (N2O).

10. The method of claim 7, wherein said oxidizing is performed at a temperature in a range from about 200° C. to about 1000° C.

11. The method of claim 7, wherein said metal-containing layer comprises tungsten.

12. The method of claim 7, wherein said forming comprises forming a barrier metal layer selected from a group consisting of tungsten nitride, titanium nitride and tantalum nitride, between the polysilicon layer and the metal-containing layer.

13. The method of claim 7, wherein said patterning is preceded by forming a hard mask pattern on the metal-containing layer.

14. A method of forming a non-volatile memory device, comprising:
forming a tunnel oxide layer, a polysilicon layer, a dielectric layer and a metal-containing layer in sequence on a substrate;
patterning the metal-containing layer, the dielectric layer, the polysilicon layer and the tunnel oxide layer to define a control gate pattern, a dielectric layer pattern, a polysilicon floating gate pattern and a tunnel oxide layer pattern; and
exposing a sidewall of the polysilicon floating gate pattern in a processing apparatus to an oxidizing plasma containing hydrogen, helium and oxygen, said exposing comprising supplying the processing apparatus with a helium gas at a first flow rate, an oxygen-containing gas at a second flow rate and a hydrogen gas at a third flow rate less than about 50% of a sum of the first, second and third flow rates.

15. The method of claim 14, wherein the third flow rate is in a range from about 0.15 times to about 0.97 times of a sum of the second flow rate and the third flow rate.

16. The method of claim 14, wherein the oxygen-containing gas is selected from a group consisting of oxygen (O2), ozone (O3), nitric oxide (NO) and nitrous oxide (N2O).

17. The method of claim 14, wherein said oxidizing is performed at a temperature in a range from about 200° C. to about 100° C.

18. The method of claim 14, wherein said metal-containing layer comprises tungsten.

19. The method of claim 14, wherein said metal-containing layer comprises a polysilicon layer and a tungsten layer.

20. A method of forming a oxide layer comprising:
selectively forming an oxide layer on a layer including silicon by a plasma process using hydrogen gas and a gas including oxygen, the hydrogen gas being controlled to have a flow rate less than about 50 percent of an overall flow rate by adding helium gas to the plasma process.
